(19) United States
(12) Patent Application Publication
(10) Pub. No.: US 2026/0178811 A1
(43) Pub. Date: Jun. 25, 2026

(54) PARALLEL ROUTING METHOD FOR TWO-STAGE PARTITIONS USING GENETIC ALGORITHM

(71) Applicant: ASICLAND Co., Ltd., Suwon-si (KR)

(72) Inventors: Jong Min LEE, Suwon-si (KR); Chang Eun JANG, Seoul (KR)

(73) Assignee: ASICLAND Co., Ltd., Suwon-si (KR)

(21) Appl. No.: 19/004,861

(22) Filed: Dec. 30, 2024

(30) Foreign Application Priority Data
Dec. 19, 2024 (KR) 10-2024-0192037

(51) Int. Cl. G06F 30/394; G06F 30/347; G06N 3/126

(52) U.S. Cl. CPC G06F 30/394; G06F 30/347; G06N 3/126

(57) ABSTRACT

Disclosed is a parallel routing method for two-stage partitions using genetic algorithms, which includes: partitioning and grouping elements constituting a circuit while maintaining a connectivity between the elements; calculating a sum of weights which a connection between any two partitioned groups has; deriving a grouping in which the calculated sum of the weights has a smallest value; generating boundary boxes for respective nets constituted by elements of the derived grouping; identifying a net having a dependency with respect to the respective nets; determining a work amount required for routing each identified net; generating a partition line; partitioning two partitioned partitions into a first partition and a second partition, and placing the other partition on any one partition; and routing the first partition and the second partition in parallel by different threads.

### CROSS-REFERENCE TO RELATED APPLICATIONS

This application claims priority to and the benefit of Korean Patent Application No. 10-2024-0192037 filed in the Korean Intellectual Property Office on Dec. 19, 2024, the entire contents of which are incorporated herein by reference.

### TECHNICAL FIELD

The present invention relates to a parallel routing method, and more particularly, to a parallel routing method for two-stage partitions using genetic algorithms, which can effectively partition a circuit through optimization of a device function and minimization of a connection, and improve a congestion cost associated with a routing resource graph without an overhead required for supplying data synchronization upon parallel routing.

### BACKGROUND ART

In the process of designing a VLSI system, a circuit to be designed is often partitioned into several sub circuits, which are designed by limiting a scale of a chip and a computational complexity size. The division of the circuit generates an on-chip connection and an off-chip connection, and the off-chip connection causes a result such as performance reduction and reliability deterioration by a connection wiring.

Japanese Patent Unexamined Publication No. JP2003-281210 relates to a layout design method and a providing method of a data library, and parameter data for a plurality of parameters for determining a layout pattern of a functional block is set as a gene, an object is evaluated by using a genetic algorithm by using a layout pattern for the gene as the object, and layout pattern data corresponding to an object that can obtain a predetermined evaluation is generated.

Logic devices such as FPGA and ASIC are used to implement a large system which can include a million of gates and megabits of an embedded memory. A complexity of the large system needs the use of an EDA tool in order to generate and optimize a system design on a physical target circuit. In a computed aided design (CAD) flow, there are synthesis, placement, and routing among procedures performed by the EDA tool.

In the past, new processors in a computer system increased a clock speed and reduced the number of cycles required per command. In this case, the EDA tool relatively maintains the routing execution time constant over several years, even if a size of a target circuit increases. However, new creators released today do not use much faster clocks than the previous models. Instead, the new generation processor has a feature of including one or more processor cores inside so that a computer can run multiple threads at the same time.

Although a limited number of parallel routing algorithms exist to use the new creation processor, the parallel routing algorithms generally require significant overhead to broadcast a large amount of data between threads to support data synchronization. Further, the previous parallel ASIC global routing and parallel FPGA routing algorithms are executed by exactly the same input, the previous parallel ASIC global routing and parallel FPGA routing algorithms do not regenerate the same routing result, so the previous parallel ASIC global routing and parallel FPGA routing algorithms are not deterministic.

### SUMMARY OF THE INVENTION

Accordingly, a first object to be achieved by the present invention is to provide a parallel routing method for two-stage partitions using genetic algorithms, which can effectively partition a circuit through optimization of a device function and minimization of a connection, and improve a congestion cost associated with a routing resource graph without an overhead required for supplying data synchronization upon parallel routing.

Further, another object is to provide a computer readable recording medium having a program for executing the method in a computer therein.

An exemplary embodiment of the present invention provides a parallel routing method for two-stage partitions using genetic algorithms, which includes: partitioning and grouping elements constituting a circuit while maintaining a connectivity between the elements; calculating a sum of weights which a connection between any two partitioned groups has; deriving a grouping in which the calculated sum of the weights has a smallest value; generating boundary boxes for respective nets constituted by elements of the derived grouping; identifying a net having a dependency with respect to the respective nets; determining a work amount required for routing each identified net; generating a partition line so that the work amount required for each partition is made to be within a predetermined range based on the determined work amount and the identified dependency, and minimize the number of boundary boxes crossing the partition to partition the target circuit into two partitions; partitioning two partitioned partitions into a first partition and a second partition, and placing the other partition on any one partition; and routing the first partition and the second partition in parallel by different threads.

According to an exemplary embodiment of the present invention, the nets having the boundary boxes crossing the partition lines partitioning the target circuit may be routed in series to a thread in which nets of a partition occupying an area relatively larger than areas of nets partitioned around the partition line are executed.

It is preferable that the numbers of elements included in the groupings are different for each group.

Another exemplary embodiment of the present invention provides a computer readable recording medium having a program for executing the parallel routing method for two-stage partitions using genetic algorithms in a computer, which is recorded therein.

According to the present invention, a circuit for minimizing an area in a layout and a propagation delay can be designed, and a congestion cost associated with a routing resource graph can be improved without an overhead required to supply data synchronization upon parallel routing with respect to a target circuit. Further, according to the present invention, the circuit is effectively designed through optimization of a device function and minimization of a connection, nets which are dependent on one or more net sets are routed, and then independent nets are last routed to reduce an idle time in threads.

### BRIEF DESCRIPTION OF THE DRAWINGS

FIGS. 1A and 1B illustrate circuits in which eight gate elements are connected.

FIG. 2 illustrates elements of the circuit are grouped, and expressed in a chromosome scheme.

FIGS. 3A and 3B illustrate another expression method of a solution substantially the same as a solution of grouping elements constituting the circuit illustrated in FIG. 2.

FIG. 4 illustrates a flowchart of a circuit partitioning method using a genetic algorithm according to an exemplary embodiment of the present invention.

FIG. 5 illustrates a flowchart of a circuit partitioning method using a cross operation according to another exemplary embodiment of the present invention.

FIG. 6 illustrates an example of a cross operation according to another exemplary embodiment of the present invention.

FIG. 7 illustrates a flowchart of a circuit partitioning method using a mutation according to yet another exemplary embodiment of the present invention.

FIG. 8 illustrates an example of a mutation operation according to still yet another exemplary embodiment of the present invention.

FIG. 9 is a flowchart illustrating a routing method using multi-threads according to an exemplary embodiment of the present invention.

FIG. 10 is a flowchart illustrating a method for statically scheduling a net according to an exemplary embodiment of the present invention.

FIG. 11 illustrates a target circuit partitioned according to the method for statically scheduling the net, which is illustrated in FIG. 10.

FIG. 12 is a flowchart illustrating a method for statically scheduling a net according to another exemplary embodiment of the present invention.

FIG. 13 illustrates a target circuit partitioned according to the method for statically scheduling the net, which is illustrated in FIG. 12.

FIG. 14 is a flowchart illustrating a method for dynamically scheduling a net according to yet another exemplary embodiment of the present invention.

FIG. 15 illustrates an example of a dependent graph according to an exemplary embodiment of the present invention.

FIG. 16 illustrates dynamic scheduling of a net according to an exemplary embodiment of the present invention.

FIG. 17 is a flowchart illustrating a method for routing a target circuit so that a routing distance is minimized according to yet another exemplary embodiment of the present invention.

FIG. 18 is a flowchart illustrating a method for performing parallel routing using two-stage partitions according to yet another exemplary embodiment of the present invention.

FIG. 19 is a flowchart illustrating a parallel routing method for two-stage partitions considering fan-out according to still yet another exemplary embodiment of the present invention.

FIG. 20 illustrates a method for placing a first partition and a second partition generated by partitioning a target circuit around a partition line into two-stage partitions according to an exemplary embodiment of the present invention.

FIG. 21 illustrates a method for placing a first partition and a second partition generated by partitioning a target circuit around a partition line into two-stage partitions according to another exemplary embodiment of the present invention.

### DETAILED DESCRIPTION

Various exemplary embodiments will now be described with reference to drawings. In this specification, various descriptions are presented to provide appreciation of the present invention.

Those skilled in the art need to recognize that various illustrative logical blocks, configurations, modules, circuits, means, logic, and algorithm steps described in connection with the exemplary embodiments disclosed herein may be additionally implemented as electronic hardware, computer software, or combinations of both sides. To clearly illustrate the interchangeability of hardware and software, various illustrative components, blocks, constitutions, means, logic, modules, circuits, and steps have been described in terms of their functionalities. Whether the functionalities are implemented as the hardware or software depends on a specific application and design restrictions given to an entire system. Skilled artisans may implement the described functionalities in various ways for each particular application. However, such implementation decisions should not be interpreted as causing a departure from the scope of the present invention.

The description of the presented exemplary embodiments is provided so that those skilled in the art of the present invention use or implement the present invention. Various modifications to the exemplary embodiments will be apparent to those skilled in the art. Generic principles defined herein may be applied to other exemplary embodiments without departing from the scope of the present invention. Therefore, the present invention is not limited to the exemplary embodiments presented herein. The present invention should be analyzed within the widest range which is coherent with the principles and new features presented herein.

Circuit partitioning in a VLSI design as a step of grouping a circuit to be designed for optimization of a function is to determine an element to be placed jointly in order to minimize an area and a propagation delay in a layout.

According to an exemplary embodiment of the present invention, a circuit to be designed may be grouped for optimization of an element function and minimization of a connection. A method is disclosed, which partitions the circuit in order to determine elements to be grouped and placed jointly for minimizing the area and the propagation delay of the circuit or reduce a calculation complexity, or satisfy a limit in chip scale. It is preferable to group respective elements so that a connection between elements separated by partitioning becomes the minimum upon circuit partitioning.

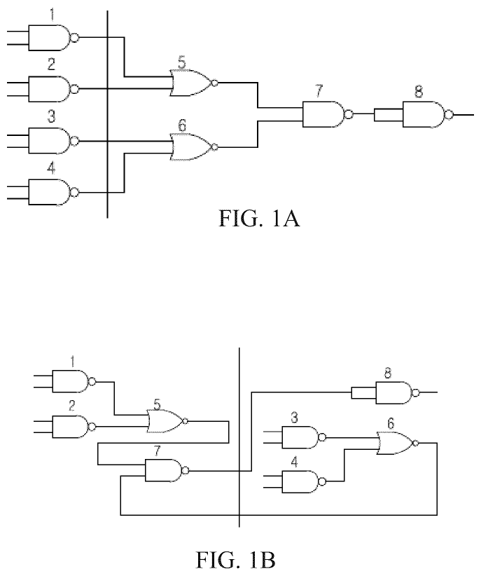

FIGS. 1A and 1B illustrate circuits in which eight gate elements are connected.

In FIG. 1A, there are four connections between two groups, but when gate elements 5, and 7, and 3, and 4 are exchanged, connections between two groups may be reduced to two as in FIG. 1B. A solution to minimize the connection between two groups may be obtained through such circuit partitioning.

A genetic algorithm as a search scheme derived from a calculation model based on an evolution process of nature is an evolution operation which simulates the evolution of living things.

The genetic algorithm encodes a [symbol] ? space by using a chromosome-like data structure to a chromosome, and evolves chromosomes by applying a recombination operator such as cross, mutation, etc., to the data structure.

The genetic algorithm starts based on a population of chromosome first arbitrarily selected, selects a parent chromosome by a predetermined scheme among chromosome groups, and crosses over the parent chromosomes to generate a child chromosome. A newly generated child chromosome is evaluated by an evaluation function, and there is a high probability that a chromosome having a high evaluation result will survive at a next generation. By such a scheme, the genetic algorithm may be close to an optimal solution through evolution of a chromosome group.

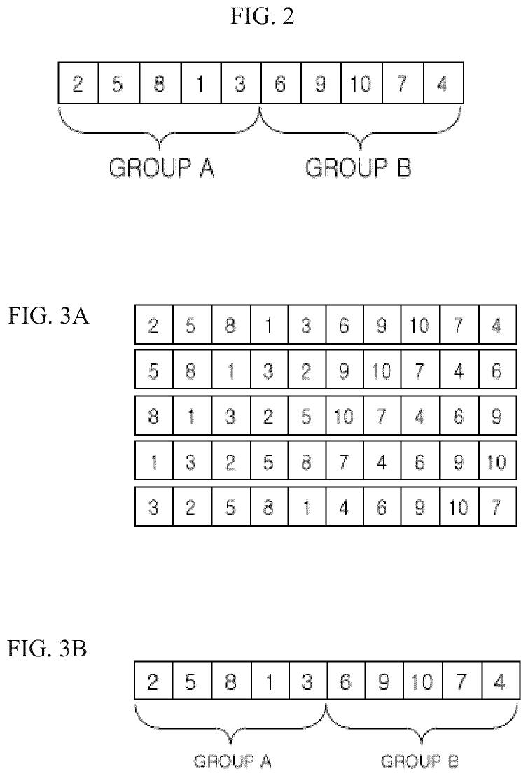

FIG. 2 illustrates elements of the circuit are grouped, and expressed in a chromosome scheme.

A circuit partitioning problem should represent a group to which respective elements belong in order to express the genetic algorithm as a circuit partitioning problem by grouping elements constituting the circuit with a minimum cost.

When it is assumed that the numbers of elements included in respective groups are the same as n in the circuit partitioning problem, the elements which belong to the respective groups may be expressed as chromosomes illustrated in FIG. 2.

Referring to FIG. 2, it is illustrated that elements 2, 5, 8, 1, and 3 belong to group A, and elements 6, 9, 10, 7, and 4 belong to group B.

FIG. 2 illustrates an expression method for one solution in a method for grouping elements constituting a circuit. The number of elements included in each group may be different for each group.

FIGS. 3A and 3B illustrates another expression method of a solution substantially the same as a solution of grouping elements constituting the circuit illustrated in FIG. 2.

It is preferable that as illustrated in FIG. 3A, various other expressions of the substantially same solution are available, and as illustrated in FIG. 3B, one solution which is substantially the same may be represented by one expression scheme by sorting elements included in each group in ascending order.

Meanwhile, while the genetic algorithm is in progress, grouping of a current population is evaluated by a specific evaluation function. The evaluation function in the circuit partitioning problem represents a sum of weights which a connection between two partitioned groups has, and evaluation functions between group A and group B are represented as cost (A, B). Here, a weight W as a unique value determined by a designer according to an importance of the circuit serves to increase a probability that elements belonging to a connection having a high weight will be included in the same group. Further, when all weights W are set to 1, the number of connections between two groups means a cost.

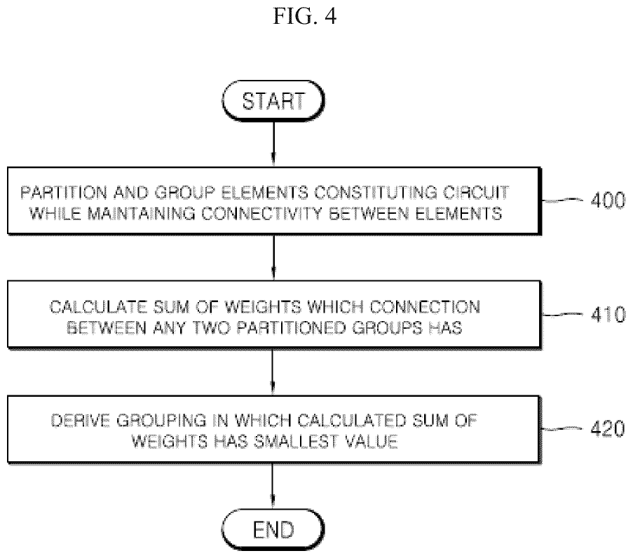

FIG. 4 illustrates a flowchart of a circuit division method using a genetic algorithm according to an exemplary embodiment of the present invention.

First, parameters for expressing the elements of the circuit by the chromosome scheme are set. That is, the number of grouping chromosomes expressing the elements constituting the circuit, the number of elements included in grouping, a mutation rate, and the maximum number of generation times may be set. Subsequently, an initial chromosome group may be generated based on the set parameter.

In step 400, the circuit is partitioned and the elements constituting the circuit are grouped while maintaining a connectivity between the elements. It is preferable that the elements are grouped so that a connection between the elements separated by partitioning is minimized when partitioning the circuit. Referring back to FIGS. 1A and 1B, in FIG. 1A, there are four connections between two groups, but connections between two groups may be reduced to two as in FIG. 1B.

In FIGS. 1A and 1B, the number of groupings of the chromosome is two, i.e., group A and group B, and the number of elements included in the groupings is the same between group A and group B as 5.

As another exemplary embodiment, it is also possible that the numbers of elements included in the groupings are configured differently. It is preferable to set the number of elements included in grouping so that the sum of weights which the connection between two partitioned groups has becomes small.

Further, in FIGS. 1A and 1B, the chromosomes are divided into two groups, and evaluated, but the chromosomes are divided into three or more, and evaluated, so the number of elements included in the grouping may also be set so that the sum of the weights which the connection between two partitioned groups has becomes small.

In step 410, a sum of weights which a connection between any two partitioned groups has is calculated. Here, a weight W as a unique value determined by a designer according to an importance of the circuit serves to increase a probability that elements belonging to a connection having a high weight will be included in the same group.

In step 420, a grouping is derived in which the calculated sum of the weights has a smallest value. In step 420, the elements for each group corresponding to the derived grouping are connected in a state of being partitioned into a circuit having a small cost, and it is preferable to store a chromosome corresponding to the grouping.

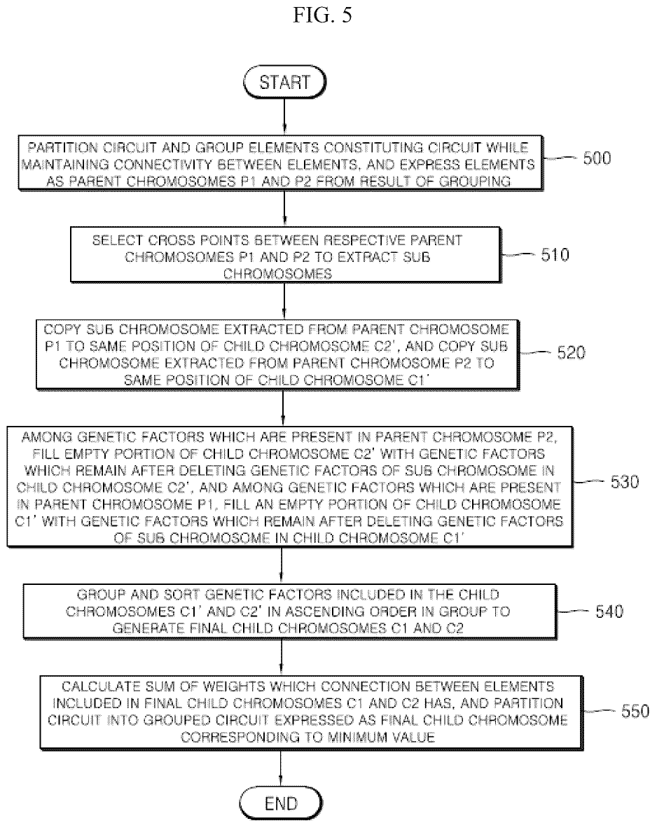

FIG. 5 illustrates a flowchart of a circuit segmentation method using a cross operation according to another exemplary embodiment of the present invention.

First, parameters for expressing the elements of the circuit by the chromosome scheme are set. That is, the number of grouping chromosomes expressing the elements constituting the circuit, the number of elements included in grouping, a mutation rate, and the maximum number of generation times may be set.

In FIGS. 1A and 1B, the number of groupings of the chromosome is two, i.e., group A and group B, and the number of elements included in the groupings is the same between group A and group B as 5.

As another exemplary embodiment, it is also possible that the numbers of elements included in the groupings are configured differently. It is preferable to set the number of elements included in grouping so that the sum of weights which the connection between two partitioned groups has becomes small.

Further, in FIGS. 1A and 1B, the chromosomes are divided into two groups, and evaluated, but the chromosomes are divided into three or more, and evaluated, so the number of elements included in the grouping may also be set so that the sum of the weights which the connection between two partitioned groups has becomes small.

Next, an initial chromosome group may be generated based on the set parameter.

In step 500, the circuit is partitioned and the elements constituting the circuit are grouped while maintaining the connectivity between the elements, and the elements are expressed as parent chromosomes P1 and P2 from a result of the grouping. Two parent chromosomes P1 and P2 may be randomly selected from the initial chromosome group.

It is preferable that the elements are grouped so that a connection between the elements separated by partitioning is minimized when partitioning the circuit. Referring back to FIGS. 1A and 1B, in FIG. 1A, there are four connections between two groups, but connections between two groups may be reduced to two as in FIG. 1B.

In step 510, cross points between the respective parent chromosomes P1 and P2 are selected to extract sub chromosomes. Sizes of the sub chromosomes extracted from the cross points of the parent chromosomes P1 and P2 may be different from each other.

In step 520, the sub chromosome extracted from the parent chromosome P1 is copied to the same position of a child chromosome C2′, and the sub chromosome extracted from the parent chromosome P2 is copied to the same position of a child chromosome C1′.

In step 530, among genetic factors which are present in the parent chromosome P2, an empty portion of the child chromosome C2′ is filled with genetic factors which remain after deleting genetic factors of a sub chromosome in the child chromosome C2′, and among genetic factors which are present in the parent chromosome P1, an empty portion of the child chromosome C1′ is filled with genetic factors which remain after deleting genetic factors of a sub chromosome in the child chromosome C1′.

In step 540, the genetic factors included in the child chromosomes C1′ and C2′ are grouped and sorted in ascending order in the group to generate final child chromosomes C1 and C2.

That is, new child chromosomes C1 and C2 are generated by using the parent chromosomes P1 and P2. A cross point between the parent chromosomes P1 and P2 may be selected with respect points in all available cases, but it is preferable to limit a range through deep learning for fast feedback.

In step 550, a sum of weights which a connection between elements included in the final child chromosomes C1 and C2 has is calculated, and partitioned into a grouped circuit expressed as the final child chromosome corresponding to a minimum value.

Meanwhile, a cost for each matting point of the parent chromosomes P1 and P2 randomly selected may be calculated, and a chromosome having a minimum cost may be stored.

When the cost for each cross point is repeatedly calculated while changing the cross point with respect to the parent chromosomes P1 and P2 randomly selected, it is preferable to store a chromosome corresponding to a cross point corresponding to a minimum value of a threshold range when the calculated cost does not deviate from a threshold range at a predetermined number of times or more.

In step 500, a chromosome having a minimum cost corresponding to another parent chromosome other than the parent chromosomes P1 and P2 randomly selected may be derived, and in step 550, a chromosome having a smaller cost than the stored chromosome having the minimum cost may be replaced with the chromosome having the minimum cost, and stored.

Further, when the sum of the weights which the connection between the elements included in the final child chromosomes C1 and C2 has is calculated, and the minimum value is calculated whenever the parent chromosomes P1 and P2 are changed, and when the minimum value is present within a predetermined range at a predetermined number of times, it is preferable to the circuit is partitioned into grouped circuits expressed as the final child chromosome corresponding to a smallest value within the predetermined range.

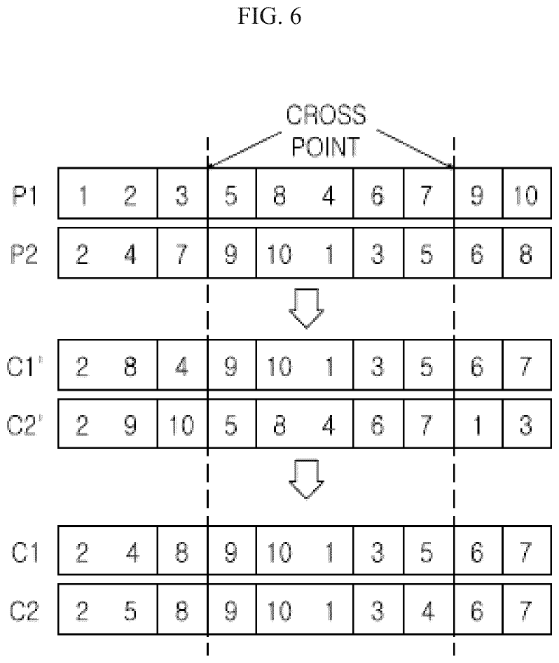

FIG. 6 illustrates an example of a cross operation according to another exemplary embodiment of the present invention.

Referring to FIG. 6, cross points which belong to respective groups are randomly selected one by one in the parent chromosomes P1 and P2.

As a next step, sub chromosomes created by two cross points in the parent chromosome P1 are copied to the same position of the child chromosome C2′. Similarly, sub chromosomes created by two cross points in the parent chromosome P2 are copied to the same position of the child chromosome C1′. As a next step, when genetic factors 5, 8, 4, 6, and 7 in the child chromosome C2′ are deleted from the parent chromosome P2, and an empty portion of C2′ is sequentially filled with the remaining genetic factors 2, 9, 10, 1, and 3 of P2, C2′ has chromosomes 2, 9, 10, 5, 8, 4, 6, 7, 1, and 3. By applying the same scheme even to the child chromosome C1′, when genetic factors 9, 10, 1, 3, and 5 in the child chromosome C1′ are deleted from the parent chromosome P1, and an empty portion of C1′ is sequentially filled with the remaining genetic factors 2, 8, 4, 6, and 7 of P1, C1′ has chromosomes 2, 8, 4, 9, 10, 1, 3, 5, 6, and 7.

Last, new generated child chromosomes C1′ and C2′ are sorted in ascending order for each group to generate final child chromosomes C1 and C2.

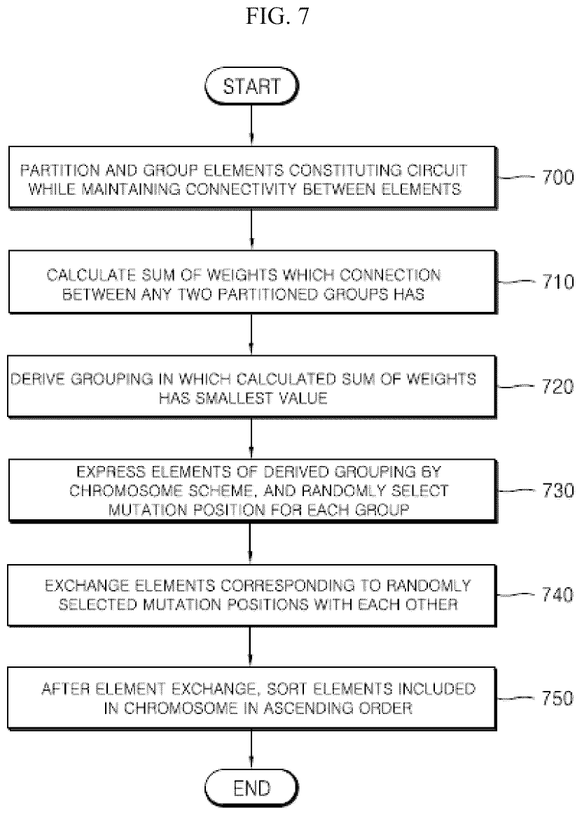

FIG. 7 illustrates a flowchart of a circuit segmentation method using a mutation according to yet another exemplary embodiment of the present invention.

In the genetic algorithm, a population of each generation converges on a population constituted by chromosomes that are close to a solution to be obtained while progressing the evolution, but results thereof may converge on a local solution other than an optimal solution, and it is preferable to perform a mutation operation in order to prevent the convergence on the local solution.

FIG. 7 illustrates a design method of partitioning the circuit by using the mutation after terminating the circuit partitioning design method of FIG. 4 or 5 when the minimum cost derived according to a result of deriving the minimum-cost chromosome does not deviate from a predetermined range according to FIG. 4 or 5.

In step 700, the elements constituting the circuit are partitioned and grouped while maintaining a connectivity between the elements. It is preferable that the elements are grouped so that a connection between the elements separated by partitioning is minimized when partitioning the circuit. Referring back to FIGS. 1A and 1B, in FIG. 1A, there are four connections between two groups, but connections between two groups may be reduced to two as in FIG. 1B. It is also possible that the numbers of elements included in the groupings are configured differently for each group.

In step 710, a sum of weights which a connection between any two partitioned groups has is calculated. Here, a weight W as a unique value determined by a designer according to an importance of the circuit serves to increase a probability that elements belonging to a connection having a high weight will be included in the same group.

In step 720, a grouping is derived in which the calculated sum of the weights has a smallest value. The elements for each group corresponding to the grouping derived in step 720 are connected in a state of being partitioned into a circuit having a low cost, and additionally, lower-cost grouping may be derived through the mutation.

In step 730, the elements of the derived grouping are expressed by the chromosome scheme, and a mutation position for each group is randomly selected.

In step 740, the elements corresponding to the randomly selected mutation positions are exchanged with each other. When the circuit partitioning method using the cross operation of FIG. 5 is used, the mutation operation may be performed by using two parent chromosomes P1 and P2.

That is, new child chromosomes C1 and C2 are generated by using the mutation-operated parent chromosomes P1 and P2. A cross point between the parent chromosomes P1 and P2 to which the mutation operation is applied may be selected with respect points in all available cross points, but it is preferable to limit the range through deep learning.

In step 750, after the element exchange, the elements included in the chromosome are sorted in ascending order.

When the circuit partitioning method using the cross operation of FIG. 5 is used, a cost for each cross point of the mutation-operated parent chromosomes P1 and P2 is calculated, and a chromosome having a minimum cost is stored.

When the cost for each cross point is repeatedly calculated while changing the cross point with respect to the mutation-operated parent chromosomes P1 and P2, it is preferable to store a chromosome corresponding to a cross point corresponding to a minimum value of a threshold range when the calculated cost does not deviate from a threshold range at a predetermined number of times or more.

Minimum-cost chromosomes are derived, which correspond to parent chromosomes which are mutation-operated at different positions from the mutation operation performed with respect to the parent chromosomes P1 and P2, and compared with already stored minimum-cost chromosomes, which may be replaced with minimum-cost chromosomes having a smaller cost, which may be stored.

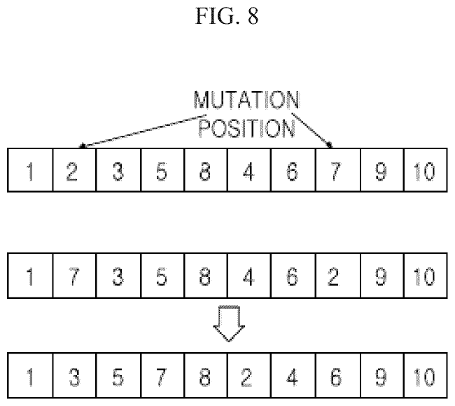

FIG. 8 illustrates an example of a mutation operation according to still yet another exemplary embodiment of the present invention.

Referring to FIG. 8, mutation points m1 and m2 which belong to respective groups in the chromosome are randomly selected (1≤m1 and m2≤n).

Next, genetic factors which belong to the selected mutation points are exchanged with each other. In FIG. 8, positions of genetic factors 2 and 7 are exchanged with each other. Last, when genetic factors of respective groups are sorted in ascending order, the mutation operation is completed.

Hereinafter, a method for generating a boundary box with respect to each of nets constituted by the grouped circuits in FIGS. 4, 5, and 7, and performing routing will be described.

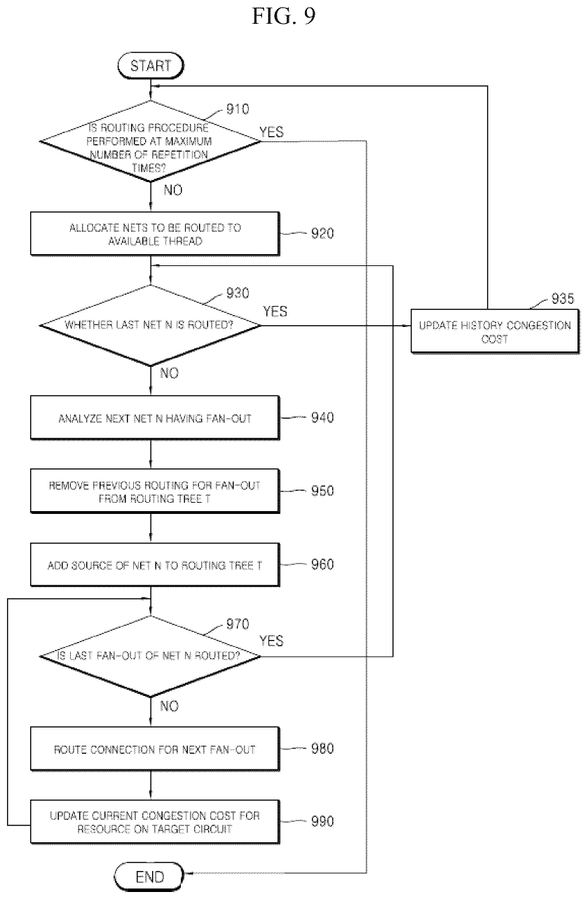

FIG. 9 is a flowchart illustrating a routing method using multi-threads according to an exemplary embodiment of the present invention.

FIG. 9 illustrates a routing method of allocating a net to a thread which may connect nets in parallel.

In step 910, the EDA tool implemented on the computer system determines whether a routing procedure is performed at the maximum number of repetition times.

According to a result of the determination in step 910, when the routing procedure is performed at the maximum number of repetition times, the routing procedure is terminated. According to the result of the determination in step 910, when the routing procedure is not performed at the maximum number of repetition times, the process proceeds to step 920.

In step 920, the EDA tool implemented on the computer system allocates nets to be routed to an available thread.

According to an exemplary embodiment of the present invention, the nets are allocated based on positions on the target circuit and relative positions to each other. The net may be allocated by using a statical scheduling approach in which a target circuit is partitioned into one or more partitions and a net corresponding to each partition is allocated to a designated thread.

During a part of the routing procedure, designated threads may be executed in parallel. According to another exemplary embodiment, the net may be allocated by using a dynamic scheduling approach in which the net is allocated based on a dependency between the nets.

In the dynamic scheduling approach, it is determined that nets having a potential to utilize the same routing resources depend on each other. A dependent net set linked jointly by the dependency is allocated to the same thread.

During the routing procedure, a plurality of threads scheduled so as for each set of nets to route an independent net set may be executed in parallel. Nets to be routed are allocated to the available thread, and then each of the threads performs a subsequent step.

In step 930, the EDA tool implemented on the computer system determines whether a last net N is routed. When it is determined that the last net N is routed, the process proceeds to step 935 and a current repetition count is increased. When it is determined that the last net N is not routed, the process proceeds to step 940.

In step 935, the EDA tool implemented on the computer system updates a history congestion cost up to now for a resource on a target circuit.

In step 940, the EDA tool implemented on the computer system analyzes a next net N having a fan-out.

In step 950, the EDA tool implemented on the computer system removes previous routing for the fan-out from a routing tree T describing a physical resource on the target circuit.

In step 960, the EDA tool implemented on the computer system adds a source of the net N to the routing tree T.

In step 970, the EDA tool implemented on the computer system determines whether a last fan-out of the net N is routed. When a last fan-out from the net N is routed, the process proceeds to step 930.

According to the determination result, when the last fan-out from the net N is not routed, the process proceeds to step 980.

In step 980, the EDA tool implemented on the computer system routes a connection for a next fan-out. According to an exemplary embodiment of the present invention, the routing tree T is added to a heap to route the connection. The heap is a sorting structure which may be used for searching a routing resource graph including a list of all available routing resources which may be used for routing the connection. After a new set of routing resources for routing a connection C are added to the routing tree, the heap may be empty.

In step 990, the EDA tool implemented on the computer system updates a current congestion cost for the resource on the target circuit. The congestion cost reflects a cost using a specific routing resource. A routing resource not used for routing may have a relatively low congestion cost, while a routing resource designated to be used for routing may have a relatively high congestion cost.

Updating the congestion cost may be performed after routing all connections in the net, and then routing each connection. After routing all nets, the process proceeds to step 970. After all nets are routed, a history congestion cost of each routing resource is updated. The history congestion cost of the routing resource is increased in a current congestion case. Before the routing procedure in step 910 is started, a history congestion of each routing resource is initialized to a low value. At the end of all routing repetitions, the history congestion for each routing resource is increased to construct a congested history which assists guiding the router so as to avoid a routing resource which tends to be excessively used. It is preferable to add a congestion of more recent repetitions more than a congestion of earlier repetitions.

Meanwhile, only a net using a current congested routing resource may be routed. This may be performed by simply changing step 940 to a step of going to a next stagnant net instead of a next net. The exemplary embodiment of the present invention may be applied to a corresponding routing by identifying all nets which involve in congestion, and generating a schedule for parallel routing of the corresponding net.

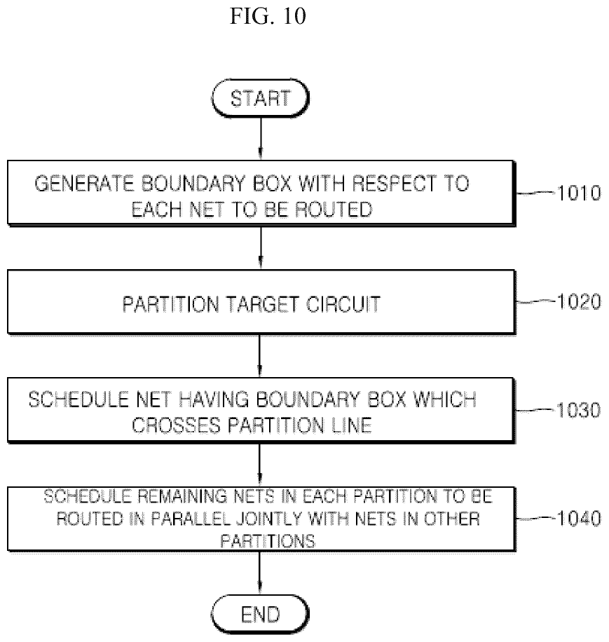

FIG. 10 is a flowchart illustrating a method for statically scheduling a net according to an exemplary embodiment of the present invention.

The method disclosed in FIG. 10 may be used to implement step 920 illustrated in FIG. 9, or used jointly with another routing procedure.

In step 1010, the EDA tool implemented on the computer system generates the boundary box with respect to each net to be routed.

According to the exemplary embodiment of the present invention, the boundary box defines the target circuit and a routing resource region, and is configured to include all terminal surroundings of the net. A purpose of the boundary box is to limit a range of the routing resource in the routing procedure. The routing procedure is not allowed to search or utilize a routing resource outside the boundary box of the net.

According to the exemplary embodiment of the present invention, when the routing resource is present in the boundary box, all routing resources should be present in the boundary box. As another exemplary embodiment, a driving point for the routing resource should be present within the boundary box in order for the routing resource to enter the boundary box. The boundary box for the net may be a smallest box for encapsulating all terminals of the net. Further, the boundary box may be made to be larger than a realizable box having a minimum size. The boundary box may be constructed separately for each terminal in the net, and here, a size of the boundary box is determined to encapsulate a specific destination and a source terminal of the net. According to an exemplary embodiment of the present invention, the boundary box may be a squarer or rectangular shape. The boundary box may also be configured to include any number of sides having any appropriate length.

In step 1020, the EDA tool implemented on the computer system partitions the target circuit. According to an exemplary embodiment of the present invention, the nets of the target circuit are partitioned to the same number as the number of threads which may be utilized for routing. In order to partition the target circuit into regions having the same size equally, one or more partitions may be used.

As another exemplary embodiment, the one or more partition lines may be used to partition the target circuit so as to maximize the number of nets in which partition lines are not crossed while balancing the number of nets among the partitions. The partition line may be a vertical line or a horizontal line.

In step 1030, the EDA tool implemented on the computer system schedules a net having a boundary box which crosses the partition line. According to an exemplary embodiment of the present invention, nets having the boundary box in which the partitions line are crossed are allocated to one of the threads, and the boundary box is routed in series.

In step 1040, the EDA tool implemented on the computer system schedules the remaining nets in each partition to be routed in parallel jointly with nets in other partitions. For example, a net which remains in a first partition may be scheduled to be routed by a first thread, and a net which remains in a second partition may be scheduled to be routed by a second thread.

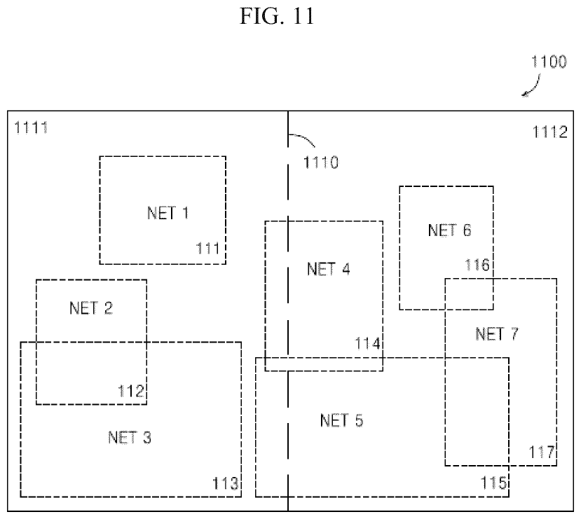

FIG. 11 illustrates a target circuit segmented according to the method for statically scheduling the net, which is illustrated in FIG. 10.

As illustrated in FIG. 11, the method for scheduling the net is referred to as a method for static scheduling.

Referring to FIG. 11, there are seven nets to be routed onto a target circuit 1100. A boundary box is generated for each net. Boundary boxes 111 to 117 are generated with respect to nets 1 to 7. For a system having two processors supporting two threads, the target circuit 1100 may be partitioned into two partitions.

The target circuit 1100 is a chip which may include a routing resource, and may be depicted as a routing resource graph. The target circuit 1100 is partitioned into one partition line 1110, and a first box 1111 and a second box 1112.

When repetition of a routing procedure is started, nets having bounding boxes crossing the partition line 1110 are routed by a first thread. In the target circuit 1100 of FIG. 11, net 4 having a boundary box 114 and net 5 having a boundary box 115 are routed in series by the first thread.

When the first thread completes routing for net 4 and net 5, a scheduler routes the net having the boundary box to a partition 1111 which is a left partition by the first thread. The scheduler allocates a net having the boundary box to a partition 1112 which is a right partition to be routed by the second thread. Here, the first and second threads are executed in parallel.

Each thread updates all current congestion costs when the nets are routed. When executing all threads is completed, the history congestion cost may be updated, and a next repetition may be started.

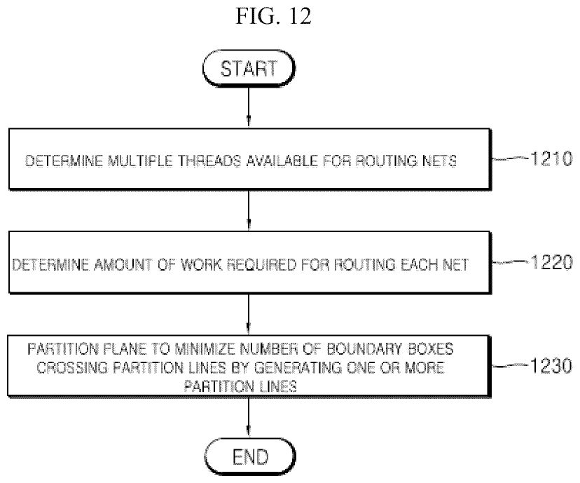

FIG. 12 is a flowchart illustrating a method for statically scheduling a net according to another exemplary embodiment of the present invention.

The method referred to in FIG. 12 is another exemplary embodiment of the method for statically scheduling the net presented in FIG. 11.

In step 1210, the EDA tool implemented on the computer system determines multiple threads available for routing the nets. According to an exemplary embodiment of the present invention, the number of available threads may directly correspond to the number of systems executing system design software, or processors or processor cores available for multiple threads available for routing the net.

In step 1220, the EDA tool implemented on the computer system determines the amount of work required for routing each net. According to the exemplary embodiment of the present invention, multiple fan-outs (external connections) are counted in each net to compute an approximate value for the amount of work for routing the net. It may be assumed that the amount of time required for routing the net is in proportion to a quantity of fan-outs in the net.

In step 1230, the EDA tool implemented on the computer system partitions a plane of a target device so as to balance the amount of work required for each partition by generating one or more partition lines, and to minimize the number of boundary boxes crossing the partition lines.

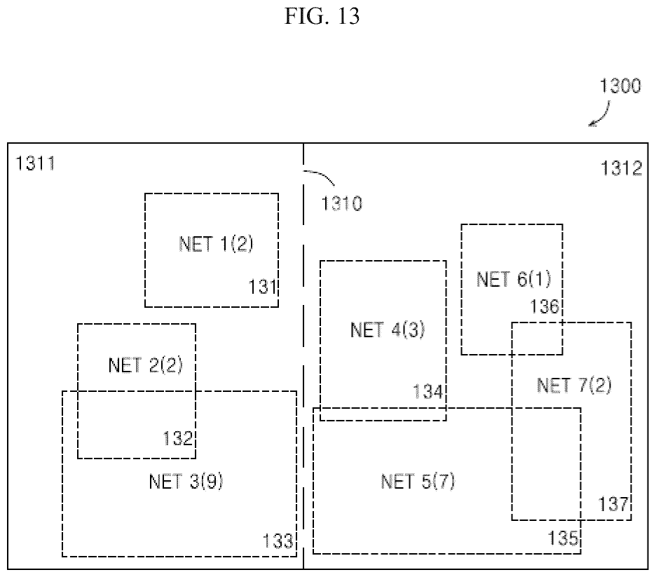

FIG. 13 illustrates a target circuit segmented according to the method for statically scheduling the net, which is illustrated in FIG. 12.

The target circuit 1300 is similar to the target circuit 1100 illustrated in FIG. 11 in that the target circuit 1300 includes net 1 to net 7 to be routed, which have boundary boxes 131 to 137.

Net 1 to net 7, and the boundary boxes 131 to 137 of FIG. 13 are located similar to net 1 to net 7, and the boundary boxes 111 to 117 illustrated in FIG. 11. Fan-outs for respective nets are shown in parentheses next to net numbers. Net 1 includes two fan-outs, net 2 includes two fan-outs, net 3 includes nine fan-outs, net 4 includes three fan-outs, net 5 includes seven fan-outs, net 6 includes one fan-out, and net 7 includes two fan-outs.

A partition line 1310 generated for the target circuit 1300 balances the amount of routed work in each of chip partitions 1311 and 1312, and minimizes the number of nets having boundary boxes crossing the partition line 1310. The partition line 1310 which is present at a center of the target circuit 1300 is generated to acquire the same number of net connection in each partition and better balance a work load for a thread which performs routing. Since the partition line 1310 does not cross the boundary box, any of the nets is scheduled not to be routed in series.

The scheduler may allocate boundary boxes and nets to the left partition 1311 to be routed by the first thread. The scheduler allocates the nets having the boundary boxes to the right partition 1312 to be routed by the second thread. It is preferable that the first and second threads are executed in parallel. Each thread updates all current congestion costs at that time when the nets are routed. When execution of all threads is completed, it is preferable that a history of a congestion cost is updated.

When all nets included in an initial partition set are routed, a set of new partitions may be generated in order to partition the remaining (not yet routed) nets into multiple net groups. It will be preferable that each group is constituted by nets completely including the boundary boxes as one of new partitions.

Accordingly, since routings of nets in different groups will not interact with each other, the nets may be routed in parallel. Each group is allocated to a different thread in order to enable parallel routing. A step of generating new partition lines may be repeated several times in order to determine a new set of independent nets which may be routed in parallel. When the remaining nets occupy most chips or an independency between the remaining nets is insufficient for other reasons, it is preferable that the remaining nets are routed in series by a single thread.

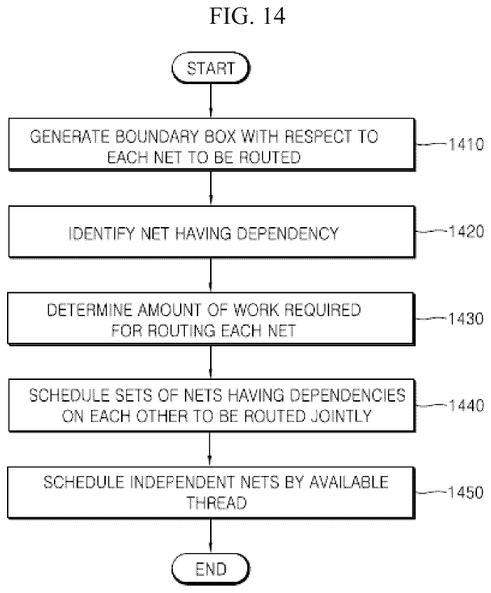

FIG. 14 is a flowchart illustrating a method for dynamically scheduling a net according to yet another exemplary embodiment of the present invention.

In step 1410, the EDA tool implemented on the computer system generates the boundary box with respect to each net to be routed.

According to the exemplary embodiment of the present invention, the boundary box defines the target circuit and a routing resource region, and is configured to include all terminal surroundings of the net. A purpose of the boundary box is to limit a range of searching the routing resource graph in the routing procedure. The routing procedure is not allowed to search or utilize a routing resource outside the boundary box of the net.

According to the exemplary embodiment of the present invention, when the routing resource is present in the boundary box, all routing resources should be present in the boundary box. As another exemplary embodiment, a driving point for the routing resource should be present within the boundary box in order for the routing resource to enter the boundary box. The boundary box for the net may be a smallest box for encapsulating all terminals of the net. Further, the boundary box may be made to be larger than a realizable box having a minimum size. The boundary box may be constructed separately for each terminal in the net, and here, a size of the boundary box is determined to encapsulate a specific destination and a source terminal of the net. According to an exemplary embodiment of the present invention, the boundary box may be a squarer or rectangular shape. The boundary box may also be configured to include any number of sides having any appropriate length.

In step 1420, the EDA tool implemented on the computer system identifies a net having a dependency. According to an exemplary embodiment of the present invention, when the net has the crossing boundary box, the first net is determined to depend on the second net. When each of the first and second nets has a boundary box which crosses a boundary box of a third net, it may be determined that the first net and the second net depend on the third net.

In step 1430, the EDA tool implemented on the computer system determines the amount of work required for routing each net. According to an exemplary embodiment of the present invention, an approximate value for the work amount for routing the net may be computed by counting the number of fan-outs of each net. It may be assumed that the amount of time required for routing the net is in proportion to multiple fan-outs in the net.

In step 1440, the EDA tool implemented on the computer system schedules sets of nets having dependencies on each other to be routed jointly. According to the exemplary embodiment, one or more nets having dependencies on each other are jointly routed by a common thread, and routed in parallel to one or more other network sets scheduled to be routed by other available common thread simultaneously with balancing the work load among the threads. Meanwhile, referring to FIG. 13, a duplicate region between nets is present, and sizes of duplicated regions are different.

That is, a duplicate region of net 7 and net 5 and a duplicate region of net 2 and net 3 are large duplicate regions, and net 4 and net 5, and net 6 and net 7 are duplicated as small regions.

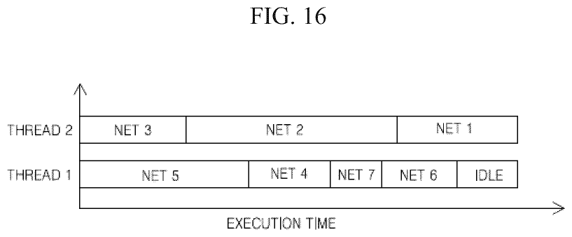

It is reasonable to see that a degree of a dependency on each other between nets is in proportion to a size of a duplicate region. Accordingly, referring to FIG. 16, it is preferable that net 5 is first routed, and net 4 is routed in thread 1 In thread 2, routing may be performed in parallel to thread 1 in order of net 3 and net 2. When the size of the duplicate region between the nets is within a predetermined range, it is preferable to first route a net having more fan-outs. When this is considered, it is preferable that routing is made in order of net 5, net 4, net 7, and net 6 in thread 1.

In step 1450, the EDA tool implemented on the computer system schedules independent nets by an available thread. According to the exemplary embodiment of the present invention, an independent net is routed after routing the dependency to the one or more net sets. By routing independent nets last, an idle time is reduced in threads.

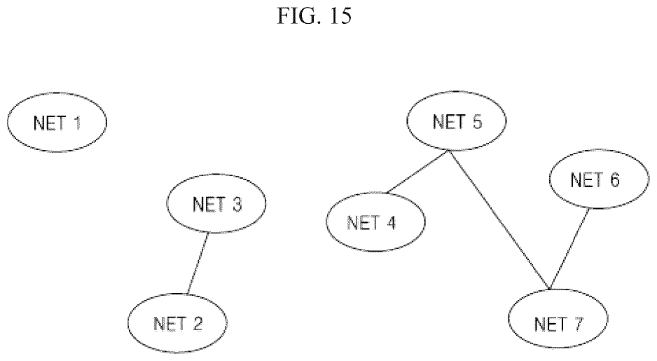

FIG. 15 illustrates an example of a dependent graph according to an exemplary embodiment of the present invention.

FIG. 15 is a dependent graph showing a relationship between net 1 to net 7 described with reference to FIGS. 11 and 13.

Referring to FIG. 15, net 1 has a boundary box which does not cross another boundary box and is an independent net. Nets 2 and 3 have boundary boxes which cross each other and depend on each other. Nets 4 and 5 have boundary boxes which cross each other. Nets 5 and 7 have boundary boxes which cross each other. Nets 7 and 6 have boundary boxes which cross each other. A dynamic scheduler should guarantee the nets which depend on each other not to be routed in parallel.

There should be no dependency between sets of various nets which are simultaneously routed in multiple threads. It is preferable to prevent boundary boxes of nets in one set from being duplicated with boundary boxes of other nets. When a set of first nets is routed, the remaining nets are examined and a new set of nets which are not dependent is calculated. In this calculation, since all already routed nets are not related to the dependency any longer, it is preferable that the nets are removed from the dependent graph.

Through this, an amount of independencies between the remaining nets may be increased. Some sets of new nets are allocated to a different thread for parallel execution, and the allocation may be repeated until a net remains while the net is not routed any longer.

FIG. 16 illustrates dynamic scheduling of a net according to an exemplary embodiment of the present invention.

Referring to FIG. 16, one possible scheduling solution is to schedule routings of nets 2 and 3 to thread 2 while scheduling routings of nets 4 to 7 to thread 1. The routing of net 1 may be scheduled to thread 2 after thread 2 completes the routings of nets 2 and 3.

According to the exemplary embodiment of the present invention, a set of multiple nets is scheduled to be routed by a thread, and a set of nets having a smaller dependency or requiring less work than a set of nets having a largest dependency or most works may be first routed. Further, when a plurality of nets are scheduled, it is preferable that a net requiring more connections, fan-outs, or more work is scheduled earlier than a net having smaller connections. When two nets have boundary boxes which do not cross each other, the two nets never search the same position of the routing resource graph, so the two nets may be routed in parallel. Since it is guaranteed that the two nets never explore or use the same routing resource, the congestion cost associated with the routing resource graph may be improved without overhead.

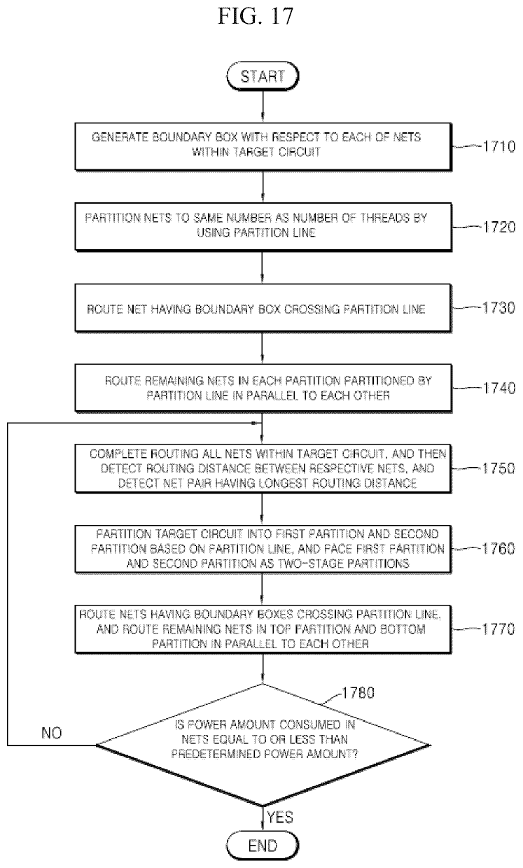

FIG. 17 is a flowchart illustrating a method for routing a target circuit so that a routing distance is minimized according to yet another exemplary embodiment of the present invention.

In step 1710, the boundary box is generated with respect to each of nets to be routed within the target circuit.

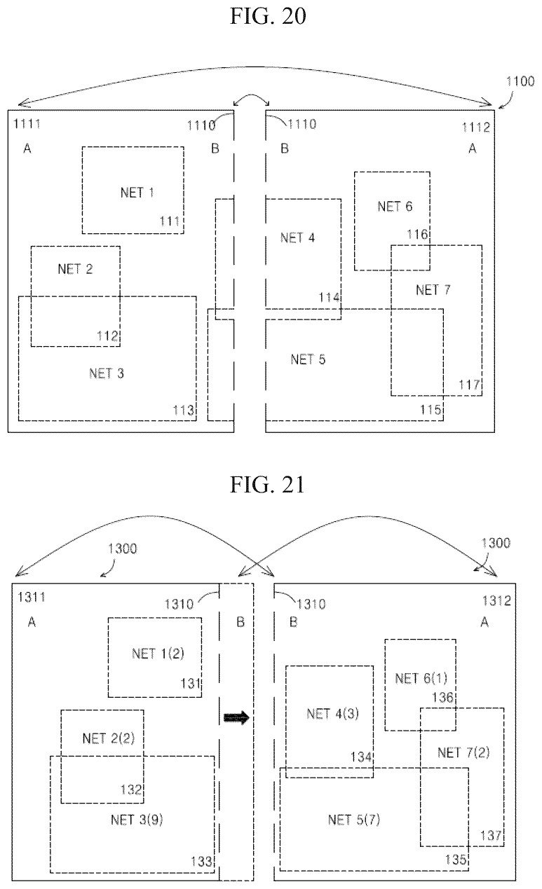

In step 1720, the nets are partitioned to the same number as the number of threads which may be utilized for routing by using the partition line. Referring to FIG. 20, for a system having two processors supporting two threads, the target circuit 1100 may be partitioned into two partitions 1111 and 1112.

In step 1730, a net having a boundary box crossing the partition line is routed. Nets having boundary boxes crossing the partition line 1110 of FIG. 20 are routed by the first thread. That is, in the target circuit 1100 of FIG. 11, net 4 having the boundary box 114 and net 5 having the boundary box 115 are routed in series by the first thread.

In step 1740, the remaining nets in each partition partitioned by the partition line are routed in parallel to each other. The scheduler routes the net having the boundary box to the first partition 1111 which is the left partition by the first thread. The scheduler allocates a net having the boundary box to the second partition 1112 which is the right partition to be routed by the second thread. Here, the first and second threads are executed in parallel.

In step 1750, routing all nets within the target circuit is primarily completed, and then a routing distance between respective nets is calculated, and a net pair having a longest routing distance is detected.

In step 1760, the target circuit is partitioned into the first partition and the second partition based on the partition line, and the other partition is placed on any one partition to reduce a distance a routing distance of the net pair having the longest routing distance to be placed as two-stage partitions to be constituted by a top partition and a bottom partition. Meanwhile, it is preferable to place nets having boundary boxes crossing a central partition line of the target circuit similarly in any one partition among the partitions when placing the other partition on any one partition.

In step 1770, the nets having the boundary boxes crossing the partition line in step 1730 above are routed earlier than the nets placed in the top partition and the bottom partition, and the remaining nets in the top partition and the bottom partition are routed in parallel to each other.

In step 1780, a power amount consumed in the nets routed in step 1770 is calculated, and steps 1750 to 1770 above are repeated until the calculated power amount is equal to or less than a predetermined power amount.

Each thread updates all current congestion costs when the nets are routed. When execution of all threads is completed, the history congestion cost is updated.

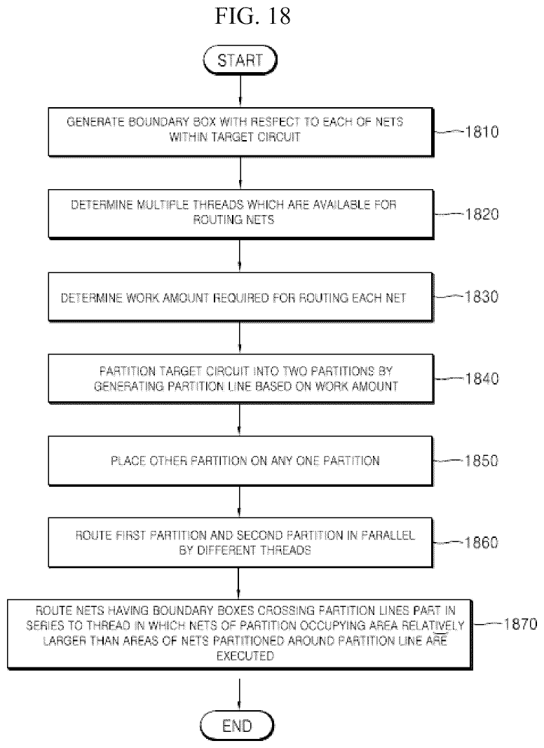

FIG. 18 is a flowchart illustrating a method for performing parallel routing using two-stage partitions according to yet another exemplary embodiment of the present invention.

In step 1810, the boundary box is generated with respect to each of the nets to be routed within the target circuit.

In step 1820, multiple threads are determined, which are available for routing the nets.

In step 1830, a work amount required for routing each net is determined.

It is preferable to estimate an approximate value for the work amount for routing each net by counting fan-outs in each net in respect to the determination of the work amount.

In step 1840, a difference in work amount allocated to the partition is adjusted within a predetermined range by generating the partition line partitioning the target circuit, and the target circuit is partitioned into two partitions so as to minimize the number of boundary boxes crossing the partition line.

In step 1850, two partitioned partitions are partitioned into the first partition and the second partition, and the other partition is placed on any one partition. Meanwhile, it is preferable to place nets having boundary boxes crossing a central partition line of the target circuit similarly in any one partition among the partitions when placing the other partition on any one partition.

In step 1860, the first partition and the second partition are routed in parallel by different threads.

In step 1870, the nets having the boundary boxes crossing the partition lines partitioning the target circuit are routed in series to a thread in which nets of a partition occupying an area relatively larger than areas of nets partitioned around the partition line are executed.

Referring to FIG. 20, net 4 and net 5 are partitioned around the partition line 1110, and a net area which belongs to the second partition 1112 is larger than an area which belongs to the first partition 1111, so it is preferable that the nets which belong to the second partition 1112 are routed in series to an executed thread.

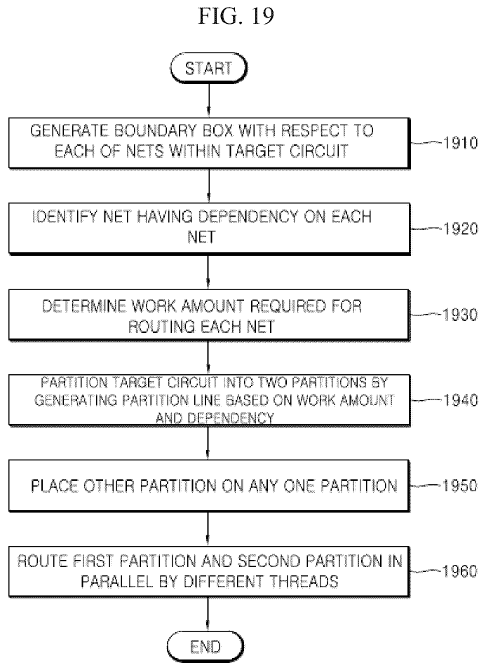

FIG. 19 is a flowchart illustrating a parallel routing method for two-stage partitions considering fan-out according to still yet another exemplary embodiment of the present invention.

In step 1910, the boundary box is generated with respect to each of nets to be routed within the target circuit.

In step 1920, a net having a dependency is identified with respect to each net.

In step 1930, a work amount required for routing each identified net is determined.

It is preferable to estimate an approximate value for the work amount for routing each net by counting fan-outs in each net in respect to the determination of the work amount.

In step 1940, the partition line is generated so that the work amount required for each partition is made to be within a predetermined range based on the determined work amount and the identified dependency, and minimize the number of boundary boxes crossing the partition line to partition the target circuit into two partitions.

In step 1950, two partitioned partitions are partitioned into the first partition and the second partition, and the other partition is placed on any one partition. Meanwhile, it is preferable to place nets having boundary boxes crossing a central partition line of the target circuit similarly in any one partition among the partitions when placing the other partition on any one partition.

In step 1960, the first partition and the second partition are routed in parallel by different threads.

It is preferable that when power amounts of independent nets are equal to or more than a predetermined level, the independent nets are set as one thread and the dependent nets are set as the other thread. The dependent nets are allocated for each thread, and then the independent nets are allocated to a thread of which execution time remains to make a time when the thread is terminated be within a predetermined time.

FIG. 20 illustrates a method for placing a first partition and a second partition generated by segmenting a target circuit around a partition line into two-stage partitions according to an exemplary embodiment of the present invention.

In the target circuit illustrated in FIG. 20, it is illustrated that the target circuit illustrated in FIG. 11 is partitioned into two partitions around the partition line 1110.

Referring to FIG. 20, there are seven nets to be routed onto the target circuit 1100.

For a system having two processors supporting two threads, the target circuit 1100 may be partitioned into two partitions 1111 and 1112.

The target circuit 1100 is partitioned into one partition line 1110, and a first partition 1111 and a second partition 1112.

First, the nets having bounding boxes crossing the partition line 1110 of FIG. 20 are routed by the first thread. That is, in the target circuit 1100 of FIG. 20, net 4 having the boundary box 114 and net 5 having the boundary box 115 are routed in series by the first thread.

When the first thread completes routing for net 4 and net 5, a scheduler routes the net having the boundary box to the first partition 1111 which is the left partition by the first thread. The scheduler allocates a net having the boundary box to the second partition 1112 which is the right partition to be routed by the second thread. Here, the first and second threads are executed in parallel.

Each thread updates all current congestion costs when the nets are routed. When execution of all threads is completed, the history congestion cost is updated.

As described above, routing all nets within the target circuit is primarily completed, and then a routing distance between respective nets is calculated, and a net pair having a longest routing distance is detected.

In a state in which the target circuit is partitioned into the first partition 1111 and the second partition 1112 around the partition line, a routing distance between respective nets is calculated.

Reducing a routing distance between a pair of nets having the longest routing distance among the calculated routing distances between the nets may become an important factor to reduce an entire routing distance.

Accordingly, in order to reduce the routing distance of the net pair having the longest routing distance, the other partition is placed on any one partition to be placed in two-stage partitions to be constituted by the top partition and the bottom partition.

For example, when a routing distance between net 2 placed in the first partition 1111 and net 7 placed in the second partition 1112 is the longest, parts A and B of the first partition 1111 are placed to face parts A and B of the second partition 1112 to minimize a routing distance between net 2 and net 7. In particular, since net 4 and net 5 belong to both the first partition 1111 and the second partition 1112, it is preferable that parts A and B of the first partition 111 are placed to face parts A and B of the second partition 1112.

Next, the nets (net 4 and net 5) having the boundary boxes crossing the partition line are routed in series to the nets which belong to the first partition 111 and the second partition 1112 placed in the two-stage partitions, and the remaining nets in the first partition 1111 and the second partition 1112 are routed in parallel to each other.

Power amounts consumed in the nets which belong to the first partition 1111 and the second partition 1112 placed in the two-stage partitions are calculated, and a two-stage partition placement is changed until the calculated power amount is equal to or less than a predetermined power amount.

That is, in order to minimize the routing distance of the net pair having the longest routing distance, routing may be performed again in the state in which the partitions are placed in the two-stage partitions, and then a net pair having a longest routing distance may be detected again, and a two-stage partition placement method may be changed to minimize a routing distance between the detected pair of nets.

FIG. 21 illustrates a method for placing a first partition and a second partition generated by segmenting a target circuit around a partition line into two-stage partitions according to another exemplary embodiment of the present invention.

In the target circuit illustrated in FIG. 21, it is illustrated that the target circuit illustrated in FIG. 13 is partitioned into two partitions around the partition line 1310.

The target circuit 1300 illustrated in FIG. 21 is similar to the target circuit 1100 illustrated in FIG. 20 in that the target circuit 1300 includes net 1 to net 7 to be routed, which have the boundary boxes 131 to 137, but is different from the target circuit 1100 illustrated in FIG. 20 in that the partition line 1310 generated for the target circuit 1300 does not cross any net.

Since the partition line 1310 does not cross the boundary box, any of the nets is scheduled not to be routed in series.

The scheduler may allocate boundary boxes and nets to the left partition 1311 to be routed by the first thread. The scheduler allocates the nets having the boundary boxes to the right partition 1312 to be routed by the second thread. It is preferable that the first and second threads are executed in parallel.

Each thread updates all current congestion costs at that time when the nets are routed. When execution of all threads is completed, it is preferable that a history of a congestion cost is updated.

As described above, routing all nets within the target circuit is primarily completed, and then a routing distance between respective nets is calculated, and a net pair having a longest routing distance is detected.

In a state in which the target circuit is partitioned into the first partition 1311 and the second partition 1312 around the partition line, a routing distance between respective nets is calculated.

Reducing a routing distance between a pair of nets having the longest routing distance among the calculated routing distances between the nets may become an important factor to reduce an entire routing distance.

Accordingly, in order to reduce the routing distance of the net pair having the longest routing distance, the other partition is placed on any one partition to be placed in two-stage partitions to be constituted by the top partition and the bottom partition.

For example, when a routing distance between net 2 placed in the first partition 1311 and net 4 placed in the second partition 1312 is the longest, part A of the first partition 1311 is placed to face part B of the second partition 1312 to minimize a routing distance between net 2 and net 4.

Next, the nets in the first partition 1311 and the second partition 1312 placed in the second-stage partitions are routed in parallel to each other.

Power amounts consumed in the nets which belong to the first partition 1311 and the second partition 1312 placed in the two-stage partitions are calculated, and a two-stage partition placement is changed until the calculated power amount is equal to or less than a predetermined power amount.

That is, in order to minimize the routing distance of the net pair having the longest routing distance, routing may be performed again in the state in which the partitions are placed in the two-stage partitions, and then a net pair having a longest routing distance may be detected again, and a two-stage partition placement method may be changed to minimize a routing distance between the detected pair of nets.

Referring to FIG. 21, the partition line 1310 generated for the target circuit 1300 does not cross even any net. Further, the first partition 1311 is formed to have a smaller area than the second partition 1312.

Accordingly, it is preferable to rout the nets in the first partition 1311 and the second partition 1312 in parallel to each other after changing the two-stage partition placement method in a state in which the first partition 1311 is extended to have the same area as the second partition 1312.

The exemplary embodiments of the present invention are implemented in a form of a program command which may be performed through various computer means and may be recorded in the computer readable medium. The computer readable medium may include a program command, a data file, a data structure, etc., singly or combinationally. The program command recorded in the medium may be specially designed and configured for the present invention, or may be publicly known to and used by those skilled in the computer software field. An example of the computer readable recording medium includes magnetic media, such as a hard disk, a floppy disk, and a magnetic tape, optical media such as a CD-ROM and a DVD, magneto-optical media such as a floptical disk, and hardware devices such as a ROM, a RAM, and a flash memory, which are specially configured to store and execute the program command. An example of the program command includes a high-level language code executable by a computer by using an interpreter and the like, as well as a machine language code created by a compiler. The hardware device may be configured to be operated with one or more software modules in order to perform the operation of the present invention and vice versa.

Further, the term “unit” used in the exemplary embodiment means software and hardware components such as field programmable gate array (FPGA) or ASIC and the “unit” performs predetermined roles. However, the “unit” is not a meaning limited to software or hardware. The “unit” may be configured to reside on an addressable storage medium and may be configured to play back one or more processors. Accordingly, as one example, the “unit” includes components such as software components, object oriented software components, class components, and task components, processes, functions, attributes, procedures, subroutines, segments of a program code, drivers, firmware, microcodes, circuitry, data, databases, data structures, tables, arrays, and variables. Functions provided in the components and the “units” may be combined into a smaller number of components and “units” or further separated into additional components and “units”. Moreover, the components and the ‘units’ may be implemented to reproduce one or more CPUs in a device or a secure multimedia card.

All functions described above can be performed by processors such as a microprocessor, a controller, a micro controller, or an application specific integrated circuit (ASIC) according to software or a program code coded to perform the above functions. Design, development, and implementation of the code will be apparent to those skilled in the art based on the description of the present invention.

While the present invention has been described with respect to the exemplary embodiments, it will be understood by those skilled in the art that various changes and modifications of the present invention may be made without departing from the technical idea and a scope of the present invention in the following claims. Accordingly, the present invention is not limited to the above-described exemplary embodiment, and the present invention will include all exemplary embodiments within the scope of the claims below.

What is claimed is:

1. A parallel routing method for two-stage partitions using genetic algorithms, comprising:
partitioning and grouping elements constituting a circuit while maintaining a connectivity between the elements;
calculating a sum of weights which a connection between any two partitioned groups has;
deriving a grouping in which the calculated sum of the weights has a smallest value;
generating boundary boxes for respective nets constituted by elements of the derived grouping;
identifying a net having a dependency with respect to the respective nets;
determining a work amount required for routing each identified net;
generating a partition line so that the work amount required for each partition is made to be within a predetermined range based on the determined work amount and the identified dependency, and minimize the number of boundary boxes crossing the partition to partition the target circuit into two partitions;
partitioning two partitioned partitions into a first partition and a second partition, and placing the other partition on any one partition; and
routing the first partition and the second partition in parallel by different threads.

2. The parallel routing method for two-stage partitions using genetic algorithms of claim 1, wherein the nets having the boundary boxes partitioning crossing the partition lines partitioning the target circuit are routed in series to a thread in which nets of a partition occupying an area relatively larger than areas of nets partitioned around the partition line are executed.

3. The parallel routing method for two-stage partitions using genetic algorithms of claim 1, wherein the numbers of elements included in the groupings are different for each group.

4. A computer readable recording medium having a program for executing the method of claim 1 in a computer, which is recorded therein.
